(19) United States
(12) Patent Application Publication
(10) Pub. No.: US 2026/0172709 A1
(43) Pub. Date: Jun. 18, 2026

(54) DEPTH IMAGE SENSOR HAVING A CHARGE-DOMAIN ARCHITECTURE

(71) Applicant: COMMISSARIAT A L'ENERGIE ATOMIQUE ET AUX ENERGIES ALTERNATIVES, Paris (FR)

(72) Inventors: Gaëlle PALMIGIANI, Grenoble (FR); Olivier SAXOD, Grenoble (FR)

(73) Assignee: COMMISSARIAT A L'ENERGIE ATOMIQUE ET AUX ENERGIES ALTERNATIVES, Paris (FR)

(21) Appl. No.: 19/417,877

(22) Filed: Dec. 12, 2025

(30) Foreign Application Priority Data
Dec. 13, 2024 (FR) FR2414058

(51) Int. Cl. H04N 25/616; H04N 25/65; H04N 25/705; H04N 25/771; H04N 25/78; H10F 39/00

(52) U.S. Cl. CPC H04N 25/616; H04N 25/65; H04N 25/705; H04N 25/771; H04N 25/78; H10F 39/80373

(57) ABSTRACT

The invention relates to a sensor comprising at least one depth pixel. A controllable storage zone comprises a charge-flow path extending vertically in line with a photosensitive region and comprising a memory region separated from the photosensitive region by a potential barrier; a transfer gate opposite the barrier; a reverse transfer gate opposite the barrier and an upper part of the photosensitive region. An additional path for flow of charges extends vertically in line with the photosensitive region and comprises a collection zone separated from the photosensitive region by a collection channel which can be controlled by a reset gate. A circuit is configured to: sample a signal received in the memory region; initialize a sense node; activate the reverse transfer and reset gates to evacuate charges from memory; read an electric potential of the sense node.

### TECHNICAL FIELD

The field of the invention is that of depth image sensors operating on a principle of measuring indirect time of flight.

### PRIOR ART

Depth image sensors allow to obtain an image in relief of a scene. These include depth image sensors based on a principle of measuring indirect time of flight, generally called iToF (Indirect Time of Flight) image sensors. Such a depth image sensor generally comprises an array of depth pixels. It is associated with a light source, for example a laser, to illuminate the scene. The light source emits a light signal that is periodic in amplitude, often sinusoidal. A pixel, or a group of contiguous pixels corresponding to a point of the image, samples the periodic signal received after reflection on the scene. The sensor comprises processing means allowing to determine a phase shift between the periodic signals emitted and received, and to convert the phase shift into a distance separating the image sensor from the point of the scene conjugated with the point of the image.

It is commonly accepted that at least three samples over a period of the periodic signal are required to perform a distance measurement. It is preferable to use at least four samples. A sample is an integration of the periodic signal received by a pixel for one or more time periods, each equal to a fraction of the period of the periodic signal, the time periods being spaced apart by a period of the periodic signal. Preferably, the fraction of the period of the periodic signal is the same for all the samples, for example equal to the reciprocal of the number of samples. Generally, the integration time periods of separate samples do not overlap.

A depth pixel typically comprises a photosensitive region configured to convert the photons of the light signal received into electric charges, as well as a transfer transistor and a sense node per sampling branch or for several sampling branches. The transfer transistor allows to transfer the electric charges from the photosensitive region to the sense node during the time periods corresponding to a sample.

Among the depth pixels operating on a principle of measuring indirect time-of-flight, there are two different families, namely charge-domain architectures and voltage-domain architectures.

In a depth pixel according to a voltage-domain architecture, the sense node is directly connected to a source or a drain of the transfer transistor. The transfer transistor switches to the on state during the integration time periods of a sample. Thus, photogenerated charges accumulate on the sense node during a sampling phase, varying a sampling potential of the sense node. The sampling potential is then read at the end of the sampling phase. The sense node must be reset between each sampling. It can be reset to a reset potential at the beginning of the sampling phase and/or after the reading of the sampling potential. The reading of the sampling potential is compared to a reading of the reset potential on the sense node to determine the value of the sample. However, the resetting of the sense node adds thermal noise to the reset potential, commonly called kTC noise, which affects the value of the sample in this type of architecture.

A charge-domain architecture allows to implement a technique for reducing the kTC noise known as Correlated Double Sampling (CDS). A depth pixel according to a charge-domain architecture comprises a memory and a second transfer transistor for each sampling branch, arranged between the transfer transistor and the sense node. The memory is consequently decoupled from the sense node by the channel of the second transfer transistor. An example of a depth pixel having a charge-domain architecture is given in the document US 2019/0086519.

The photogenerated charges accumulate in the memory during the integration time periods of a sample. At the end of the sampling phase, the sense node is reset to a reset potential which is read before a transfer of the electric charges stored in the memory to the sense node by activation of the second transfer transistor. A reading of the potential of the sense node after transfer is subtracted from the read value of the reset potential to obtain the value of the sample. Since the two readings occur immediately one after the other, without switching of a switch, the kTC noises are correlated and are therefore eliminated during the subtraction.

For a charge-domain architecture, the memory is however cumbersome and often occupies a blind region of the depth pixel. However, it is not desirable to reduce its footprint at the risk of compromising a dynamic range of the samples, that is to say the maximum difference between two sample values that the depth pixel or the image sensor can record simultaneously. This constraint is all the more exacerbated when the size of the depth pixel is reduced to increase a resolution of the sensor, or when the photosensitive region is large to increase its sensitivity.

Specific image sensors exist, often called RGBZ sensors, allowing to obtain an intensity image of a scene containing information about distance between the sensor and the scene. Such sensors generally comprise a plurality of blocks of pixels, each block of pixels comprising an image group of at least one intensity pixel and a macro-pixel Z of at least one depth pixel. The image group is configured to give information about intensity of an observed scene. The macro-pixel Z is configured to give information about distance separating the scene from the sensor. In an RGBZ sensor, the image group generally consists of three intensity pixels, one sensitive pixel in red, one in green and one in blue. All the pixels are arranged into an array. It is consequently preferable that the depth pixels have substantially the same size as the intensity pixels. It is therefore desirable that the size of the depth pixels follow the same reduction trend as the intensity pixels. This often makes it difficult or even impossible to adopt a charge-domain architecture.

There is therefore a need for a more compact depth pixel and/or a new depth pixel architecture allowing correlated double sampling, without compromising on the size of the depth pixel, the resolution or the sensitivity of the image sensor.

### DISCLOSURE OF THE INVENTION

The goal of the invention is to at least partially overcome the disadvantages of the prior art, and more particularly to propose an image sensor comprising a plurality of pixels, at least one of which is a depth pixel more compact than the depth pixels of the prior art.

For this, the object of the invention is a sensor of an image comprising a readout circuit and a plurality of pixels formed in and/or on a semiconductor substrate of the sensor, such that at least one of the pixels is a depth pixel. Each depth pixel comprises a photosensitive region of the substrate and a controllable storage zone.

The controllable storage zone comprises a path for charge-flow path extending vertically in the substrate vertically in line with the photosensitive region and comprising a potential well called memory region and a potential barrier called barrier interposed between the memory region and the photosensitive region; a transfer gate extending vertically in the substrate vertically in line with the photosensitive region, opposite the barrier; a reverse transfer gate extending vertically in the substrate opposite the barrier and opposite an upper part of the photosensitive region.

Each depth pixel further comprises an additional charge-flow path extending vertically in the substrate vertically in line with the photosensitive region comprising a potential well called collection zone and a potential barrier, called collection channel, interposed between the collection zone and the photosensitive region.

Each depth pixel further comprises a reset gate extending vertically in the substrate vertically in line with the photosensitive region, opposite the collection channel.

The readout circuit comprises a sense node electrically connected to the collection zone. It is configured to successively: apply a periodic pulse train to the transfer gate during a sampling phase so as to make electric charges flow from the photosensitive region to the memory region during the pulses; reset the sense node; activate the reverse transfer gate and the reset gate so as to make electric charges flow from the memory region to the collection zone during a charge evacuation phase; read an electric potential Vsig of the sense node.

Some preferred, yet non-limiting, aspects of this sensor are as follows.

The readout circuit can be configured to read an electric potential Vinit of the sense node prior to the charge evacuation phase and after the reset of the sense node, wherein the sensor can be such that it comprises means for carrying out a correlated double sampling using Vinit and Vsig.

The flow path of the controllable storage zone can comprise a pinning zone covering the memory region on a side of the memory region opposite to the barrier. The controllable storage zone can comprise a pinning gate which can extend vertically in the substrate opposite the memory region. The readout circuit can be configured to apply a difference in electric potential between the pinning zone and the pinning gate so as to passivate the memory region using electric charges coming from the pinning zone.

The pinning gate can be housed in a notch made in the reverse transfer gate.

The readout circuit can further be configured to activate the transfer gate during the charge evacuation phase after activation of the reverse transfer gate.

The readout circuit can be configured to activate the reset gate in opposite phase with the transfer gate during the sampling phase.

For each depth pixel, the transfer gate can extend opposite the memory region.

For each depth pixel, the barrier, the memory region, and the collection zone can be doped with a first type of conductivity. They can have dopant concentrations equal to N1, N2, N3, respectively. N1 can be strictly less than N2. N2 can be strictly less than N3.

For each depth pixel, the pinning zone can be doped with a second type of conductivity opposite to the first type of conductivity.

The collection channel can have a dopant concentration equal to N1.

For each depth pixel, the transfer gate can have the shape of a U in a top view, surrounding the flow path of the controllable storage zone.

The plurality of pixels can be arranged in an array. Each pixel can comprise a peripheral isolation trench which can extend vertically in a peripheral region of the pixel facing a photosensitive region of the pixel. The readout circuit can be configured to apply a fixed electric potential common to all the peripheral isolation trenches.

Each pinning gate and each reverse transfer gate can be arranged in separation planes of two contiguous pixels of the array of pixels.

The peripheral isolation trenches can form a continuous mesh comprising cells such that each cell surrounds two pixels. The readout circuit can be electrically connected to a peripheral zone of the mesh so as to apply the common fixed electric potential.

All the pixels in the array can have the same size. The array of pixels can comprise intensity pixels configured to deliver a signal representative of an intensity of an incident light radiation.

### BRIEF DESCRIPTION OF THE DRAWINGS

Other aspects, aims, advantages and features of the invention will become apparent upon reading the following detailed description of preferred embodiments thereof, provided as a non-limiting example, and made with reference to the appended drawings wherein:

FIG. 1A is a schematic top view of an example of a depth pixel according to the invention;

FIG. 1B is a schematic view according to the section A-A of FIG. 1A of the example of a depth pixel;

FIG. 2A is an electrical schematic of a readout circuit adapted to the depth pixel of FIGS. 1A and 1B;

FIG. 2B is a timing diagram illustrating a possible operation of the readout circuit;

FIGS. 3A to 3D illustrate variations in electric potentials within the depth pixel of FIGS. 1A and 1B;

FIG. 4 is a partial schematic top view of an array of depth pixels;

FIG. 5 is a partial schematic top view of an array of pixels mixing intensity pixels and depth pixels;

FIG. 6 is a schematic view according to the section A-A of FIG. 5 or FIG. 6.

### DETAILED DISCLOSURE OF SPECIFIC EMBODIMENTS

In the figures and in the following description, the same references represent identical or similar elements. Furthermore, the different elements are not represented to scale so as to improve the clarity of the figures. Moreover, the different embodiments and alternatives are not mutually exclusive and could be combined together. Unless stated otherwise, the terms “substantially”, “about”, and “in the range of” mean within a 10% margin, and preferably within a 5% margin. Moreover, the terms “between . . . and . . . ” and equivalents mean that the bounds are included, unless specified otherwise.

The invention relates to a sensor of an image. The sensor comprises a substrate, a readout circuit and a plurality of pixels formed in and/or on the substrate. At least one out of the plurality of pixels is a depth pixel.

Each depth pixel comprises a photosensitive region and a controllable storage zone arranged vertically in line with the photosensitive region. The controllable storage zone comprises a charge-flow path, a transfer gate and a reverse transfer gate. The flow path comprises a memory region separated from the photosensitive region by a barrier.

Each depth pixel further comprises an additional charge-flow path, also arranged vertically in line with the photosensitive region, comprising a collection zone separated from the photosensitive region by a potential barrier called collection channel.

The gates extend vertically in the substrate. The transfer gate is vertically in line with the photosensitive region. A sense node of the readout circuit is electrically connected to the collection zone. The transfer gate and the reverse transfer gate extend opposite the barrier, so that the latter can be controlled indifferently by the transfer gate or by the reverse transfer gate, or by both simultaneously. Furthermore, the reverse transfer gate extends opposite an upper part of the photosensitive region, so as to be able to change the sign of a difference in electric potentials between the memory region and the photosensitive region.

This arrangement in combination with a specific configuration of the readout circuit allows to control the storage zone so as to allow a two-way flow of the electric charges in the flow path. It is thus possible to accumulate photogenerated electric charges in the memory region during a sampling phase and to evacuate them during a reading phase to the collection zone. An electric potential of the sense node is then read by the readout circuit. It corresponds to the number of charges accumulated, then transferred. The memory region thus emptied can be used as a receptacle for a new sampling phase.

During operation, the photosensitive region is intended to receive incident electromagnetic radiation on a lower face of the substrate opposite to the controllable storage zone. Thus, the depth pixel is compact and has no or few blind regions.

Specific embodiments will be described relating to a sensor of an image comprising a readout circuit containing NMOS transistors. However, these embodiments can be adapted to other types of readout circuits allowing to implement the technical teaching of the description without going beyond the scope of the invention. For example, it is possible to use a readout circuit containing PMOS transistors or containing a combination of NMOS and PMOS transistors.

Similarly, each embodiment described below adopts a specific combination of conductivities associated with the doped zones, with it being understood that the combination can be inverted without going beyond the scope of the invention. Thus, for one specific embodiment, all the P-doped zones can be N-doped and all the N-doped zones can be P-doped, provided that the type of conductivity of all the doped zones is changed. The examples of electric potentials or bias voltages given in the description are given relative to the specific combination of conductivities and doping concentrations taken for the exemplary embodiments, in association with an example of an NMOS readout circuit. A person skilled in the art is capable of establishing the electric potentials and/or the bias voltages suitable for other possible combinations within the scope of the invention.

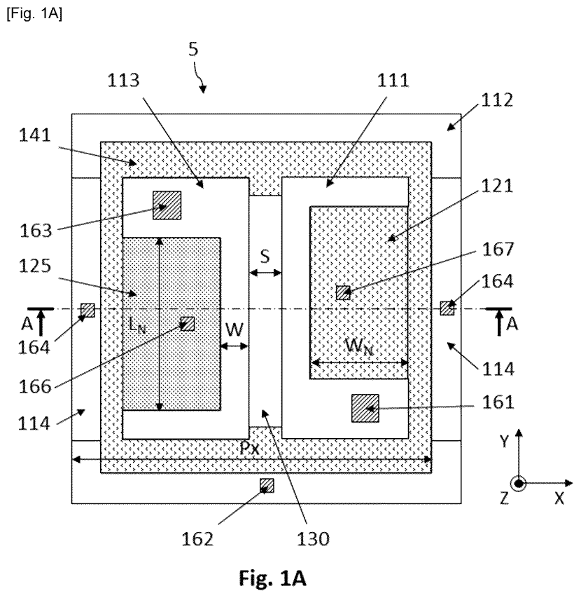

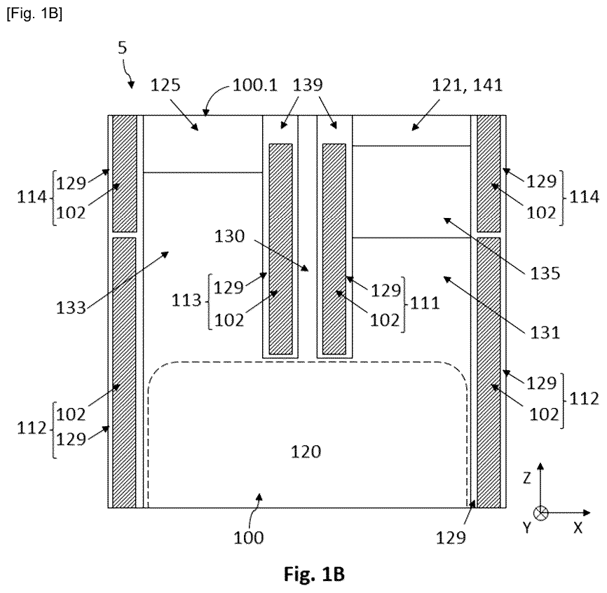

An example of a depth pixel 5 of a sensor of an image according to the invention will now be described in relation to FIGS. 1A and 1B. FIGS. 1A and 1B are schematic top and cross-sectional views, respectively. The cutting plane of FIG. 1B is represented by a dash-dotted line in FIG. 1A.

The sensor of an image comprises a readout circuit and a plurality of pixels formed in and on a substrate 100, at least one of which is a depth pixel 5. In FIGS. 1A to 1B, only one depth pixel 5 of the sensor is shown. In order not to overload the diagrams, some elements have been omitted, for example such as the interconnection lines or certain electric contacts. To improve the readability thereof, only an upper part of the substrate 100 is shown in the cross-sectional views. In the schematic views, the elements are represented by simple geometric shapes. The latter are reproduced in the device produced plus or minus manufacturing errors, such as alignment, dimensional errors or corner rounding caused by a lack of resolution.

The substrate 100 comprises an upper face 100.1 and a lower face opposite to the upper face 100.1. The lower face and upper face 100.1 are substantially flat and parallel to each other. The depth pixel 5 comprises a photosensitive region 120, a controllable storage zone. The controllable storage zone comprises a flow path. The flow path comprises a barrier 131, a memory region 135 and a pinning zone 121.

The depth pixel 5 further comprises an additional flow path and a reset gate 113. The additional flow path comprises a collection zone 125 and a collection channel 133. In this example, the pinning zone 121 and the collection zone 125 are flush with the upper face 100.1. The flow path of the controllable storage zone and the additional flow path extend vertically in the substrate 100 vertically in line with the photosensitive region 120, between the photosensitive region 120 and the upper face 100.1 of the substrate 100.

Here and for the remainder of the description, an orthogonal three-dimensional right-handed coordinate system (X, Y, Z) is defined, in which the axes X and Y form a plane parallel to the upper face 100.1 of the substrate 100, the axis X being oriented in the cutting plane A-A, and in which the axis Z is oriented substantially orthogonally to the upper face 100.1, from the photosensitive region 120 towards the upper face 100.1. In the following description, the terms “vertical” and “vertically” are defined as relating to an orientation substantially parallel to the axis Z, and the terms “horizontal” and “horizontally” as relating to an orientation substantially parallel to the plane (X, Y). Furthermore, the terms “lower” and “upper” are defined as relating to an increasing positioning when moving away from the upper face 100.1 of the substrate 100, in the direction +Z. The term “lateral” refers to an orientation substantially parallel to the axis Z.

The substrate 100 is made of a semiconductor material. Here it is made of crystalline silicon. For example, it consists of a silicon wafer or part of a silicon wafer. It can comprise one or more epitaxial crystalline silicon layers, and also one or more passivation layers.

The barrier 131 is arranged between the photosensitive region 120 and the memory region 135. The barrier 131 constitutes an electric potential barrier for electric charges intended to be photogenerated in the photosensitive region 120. The photogenerated electric charges here are electrons of a conduction band of the photosensitive region 120. The memory region 135 constitutes an electric potential well for the photogenerated electric charges.

The pinning zone 121 covers the memory region 135, on a side of the memory region 135 opposite to the barrier 131. The pinning zone 121 preferably completely covers the memory region 135. The controllable storage zone further comprises a pinning gate 114. The pinning gate 114 extends vertically in the substrate 100 opposite the memory region 135. The pinning zone 121 and/or the pinning gate 114 are intended to set a “pinch-off” electric potential of the memory region 135. Preferably, the pinning zone 121 and/or the pinning gate 114 are intended to deplete the memory region 135 in the absence of photogenerated electric charges.

The controllable storage zone further comprises a transfer gate 111, a reverse transfer gate 112. The transfer gate 111 extends vertically in the substrate 100 vertically in line with the photosensitive region 120 between the upper face 100.1 and the photosensitive region 120. It extends opposite the barrier 131. Preferably, as is the case here, it extends vertically opposite the memory region 135.

The reverse transfer gate 112 extends vertically in the substrate 100 opposite the barrier 131 and an upper part of the photosensitive region 120, preferably opposite the entire photosensitive region 120. Advantageously, the reverse transfer gate 112 extends substantially to the lower face of the substrate 100. Here, it defines the photosensitive region 120 in a horizontal plane. When viewed from above, it surrounds the photosensitive region 120 on all sides and has a closed contour, here having a substantially square shape, with sides parallel to the axis X or to the axis Y. In a plane parallel to the upper face 100.1, the distance Px separating an outer edge on one side of the square from an inner edge on the opposite side of the square defines a size of the pixel. In this example, the size Px of the pixel is equal to 1.2 μm. It can be less than or equal to 1.2 μm, or even less than or equal to 1 μm.

One or more horizontal distances separating the transfer gate 111 from the reverse transfer gate 112 at the barrier 131 and a concentration of dopant elements of the barrier 131 are capable of creating an electric potential barrier at the barrier 131, between the photosensitive region 120 and the memory region 135. Similarly, one or more horizontal distances separating the transfer gate 111 from the pinning gate 114 and a dopant concentration of the memory region 135 are capable of creating an electric potential well at the memory region 135, between the barrier 131 and the pinching zone 121. The transfer gate 111 and the reverse transfer gate 112 are facing each other at the barrier 131 so that the latter can be controlled indifferently by either of the transfer gate 111 or the reverse transfer gate 112, or simultaneously by both.

In this example, the photosensitive region 120, the barrier 131 and the memory region 135 are doped with a first type of conductivity. Here, the first type of conductivity is of the n type. The barrier 131 and the memory region 135 have dopant concentrations equal to N1 and N2, respectively, such that N1 is strictly less than N2.

The barrier 131 extends horizontally from the transfer gate 111 to the reverse transfer gate 112. The memory region 135 extends horizontally from the transfer gate 111 to the pinning gate 114. Here, the pinning gate 114 occupies a notch made in the reverse transfer gate 112. It is substantially flat.

The collection channel 133 is arranged between the photosensitive region 120 and the collection zone 125. The collection channel 133 constitutes an electric potential barrier for the electric charges intended to be photogenerated in the photosensitive region 120. The collection zone 125 constitutes an electric potential well for the photogenerated electric charges.

The reset gate 113 extends vertically in the substrate 100 vertically in line with the photosensitive region 120, opposite the collection channel 133. Here, the reverse transfer gate 112 extends vertically opposite the collection channel 133. Optionally, like here, the depth pixel 5 can comprise an additional pinning gate 114 extending vertically opposite the collection zone 125. In this example, the additional pinning gate 114 has all its dimensions identical to the pinning gate 114 of the controllable storage zone. The two pinning gates 114 are symmetrical to each other with respect to a plane of symmetry parallel to the plane (Y, Z) passing through the center of the depth pixel 5. The reverse transfer gate 112 is symmetrical with respect to this plane. The additional pinning gate 114 can extend opposite the collection channel 133, in part or entirely.

One or more horizontal distances separating the reset gate 113 from the reverse transfer gate 112 at the collection channel 133 and a dopant concentration of the collection channel 133 are capable of creating an electric potential barrier at the collection channel 133, between the photosensitive region 120 and the collection zone 125. Similarly, one or more horizontal distances separating the reset gate 113 from the additional pinning gate 114 and a dopant concentration of the collection channel 133 are capable of creating an electric potential well at the collection zone 125 and an electric potential barrier between the photosensitive region 120 and the collection zone 125.

In this example, the collection channel 133 and the collection zone 125 are doped with the first type of conductivity. The collection zone 125 has a dopant concentration equal to N3, such that N2 is strictly less than N3. The collection channel 133 can have a dopant concentration equal to the barrier 131, as is the case in this example. If applicable, the doping of the collection channel 133 and of the barrier 131 can result from in-situ doping during growth by epitaxy. The growth by epitaxy can comprise the formation of the photosensitive region 120.

The collection channel 133 extends horizontally from the reset gate 113 to the reverse transfer gate 112. The collection zone 125 extends horizontally from the reset gate 113 to the additional pinning gate 114.

All the gates of the depth pixel 5 out of a set of gates consisting of the transfer gate 111, the reverse transfer gate 112, the pinning gate 114, the additional pinning gate 114, and the reset gate 113 can each be flush with the upper face 100.1 of the substrate 100, without this being mandatory. Each gate of the set of gates comprises an electrode 102 made of an electrically conductive material, such as a metal or a doped semiconductor. The electrodes 102 are advantageously made of the same material. Here, they are all made of doped polycrystalline silicon. They are doped with a second type of conductivity opposite to the first type of conductivity, that is to say p-doped in this example.

The photosensitive region 120 can be doped or intrinsic. A geometry of the reverse transfer gate 112 and a dopant concentration of the photosensitive region 120 are such that the memory region 135 has an intermediate electric potential between an electric potential of the photosensitive region 120 and an electric potential of the collection zone 125, when all the gates of the set of gates are at the same electric potential. The electric potential of the photosensitive region 120 can be equal to the electric potential of the memory region 135.

The electrode 102 of each gate of the set of gates is coated with a dielectric coating 129 of the gate. The dielectric coatings 129 are made of any dielectric material. Here they are made of silicon oxide. Each gate is electrically insulated from the semiconductor substrate 100 by a dielectric coating 129. A dielectric coating 129 electrically insulates the electrode 102 of the pinning gate 114 from the electrode 102 of the reverse transfer gate 112, as well as the electrode 102 of the additional pinning gate 114 from the electrode 102 of the reverse transfer gate 112.

The transfer 111 and reset 113 gates each comprise an insulating region 139 covering their respective electrodes 102 and flush with the upper face 100.1 of the substrate 100. The insulating regions 139 are made of any dielectric material. Here they are made of silicon oxide.

The pinning zone 121 is doped with the second type of conductivity, p-doped in this example. It advantageously comprises a peripheral doped zone 141 extending horizontally in a peripheral region of the depth pixel 5. The pinning zone 121 has a dopant concentration P1. It can extend deeper into the substrate 100 at its peripheral doped zone 141. In this example, it extends vertically in the substrate 100 over a substantially constant depth, for example greater than or equal to a height along the axis Z of the insulating regions 139. The pinning zone 121 with its peripheral doped zone 141 can for example be obtained by a single localized implantation step. Here, the peripheral doped zone 141 surrounds the transfer gate 111 and the reset gate 113. It has an outer contour in contact over its entire surface with a gate out of the pinning gate 114, the additional pinning gate 114 and the reverse transfer gate 112.

The reset gate 113 is arranged in the depth pixel 5 so as to screen in the collection channel 133 an electric field emitted by the transfer gate 111, when the sensor is in operation. Similarly, the transfer gate 111 is arranged so as to screen in the barrier 131 an electric field emitted by the reset gate 113, when the sensor is in operation. This is achieved here by interposing the transfer gate 111 and the reset gate 113 between the two flow paths. The transfer 111 and reset 113 gates are separated by a distance S measured parallel to the X axis, at an inter-gate region 130 of the depth pixel 5. By way of example, the distance S is between 10 nm and 300 nm, here equal to 70 nm. The inter-gate region 130 separating the transfer gate 111 from the reset gate 113 is made of any dielectric or a doped or undoped semiconductor material. Here it is made of crystalline silicon. In this example, it is n-doped. It has a concentration of dopant elements equal to N1.

The transfer gate 111 has the shape of a U in a top view, surrounding the flow path. It comprises a main portion forming the base of the U, extending parallel to the plane (Y, Z), as well as a first branch and a second branch of the U extending parallel to the plane (X, Z). In this example, the main portion and the first branch have horizontal widths substantially equal to a value W. The second branch here has a horizontal width strictly greater than W. The horizontal width of the second branch is for example sufficient to guarantee that a first contact 161 of the readout circuit rests entirely on the second branch despite manufacturing uncertainties. W is equal to 110 nm here. The width of the second branch is here equal to 200 nm. The first and second branches have lengths equal to W_{N}, measured parallel to the axis X. W_{N} is equal to 336 nm here. The first branch is separated from the second branch by a distance L_{N} measured parallel to the axis Y, here equal to 640 nm.

In this example, the reset gate 113 is symmetrical to the transfer gate 111 by axial symmetry with respect to a vertical axis of symmetry passing through the center of the depth pixel 5. The transfer gate 111 and/or the reset gate 113 can however have other shapes in a top view, independently of one other, for example the shape of an L or an I, with or without serifs.

In this example, the reverse transfer gate 112 has a horizontal width substantially constant over its entire contour, here equal to 100 nm. The pinning gate 114 and the additional pinning gate 114 are aligned on respective faces of the reverse transfer gate 112. Here, they have a horizontal width equal to that of the reverse transfer gate 112.

Preferably, the collection zone 125 extends deep into the substrate 100 from the upper face 100.1, deeper than the insulating regions 139. It extends less deeply than the additional pinning gate 114. The memory region 135 extends deep from the pinning zone 121 to the barrier 131. The pinning gate 114 extends deep into the substrate 100 from the upper face 100.1. Preferably, it extends until it substantially reaches a separation plane between the memory region 135 and the barrier 131, plus or minus manufacturing uncertainties.

The respective electrodes 102 of the pinning gate 114 and of the reverse transfer gate 112 are insulated from one other by the dielectric coating 129. They are for example separated by the dielectric coating 129 by a distance of between 2 nm and 100 nm, here equal to 20 nm. Similarly, the respective electrodes 102 of the additional pinning gate 114 and of the reverse transfer gate 112 are separated by the dielectric coating 129 by an equivalent distance. Here, the dielectric coatings 129 of all the electrodes 102 of the set of gates have substantially equal thicknesses.

N1 is for example between 1E10 at/cm³ and 1E18 at/cm³. N2 is for example between 1E16 at/cm³ and 1E19 at/cm³. N3 is for example between 1E17 at/cm³ and 5E20 at/cm³. P1 is for example between 1E17 at/cm³ and 5E20 at/cm³.

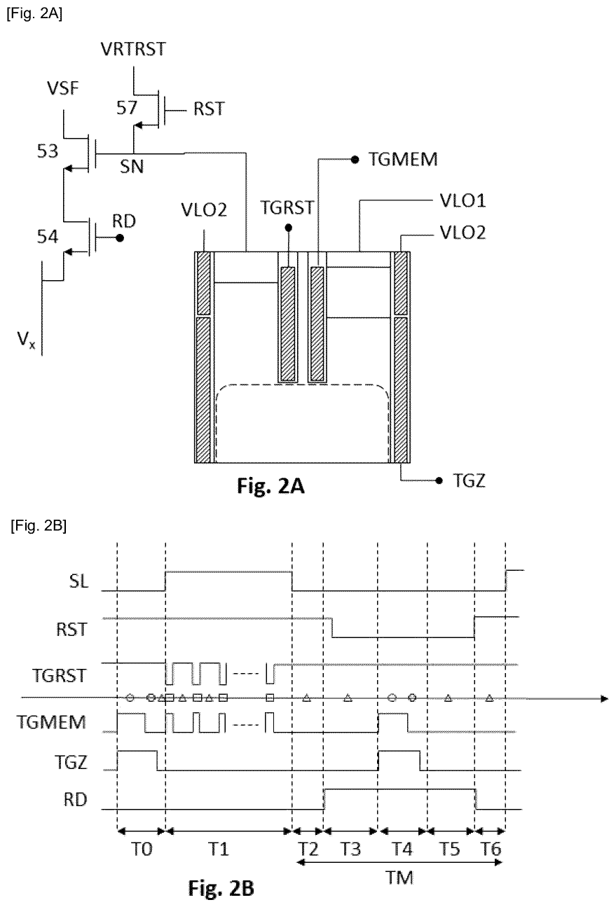

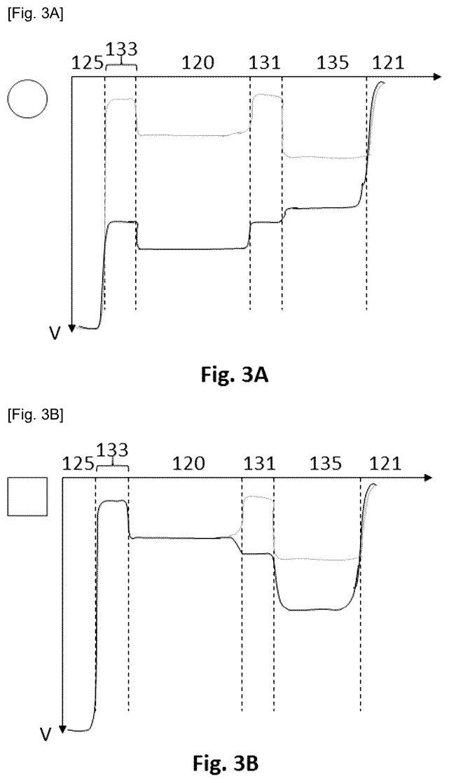

In relation to FIG. 2A, a readout circuit of the sensor, adapted to the example of a depth pixel 5 of FIGS. 1A and 1B, will now be described. FIG. 2A shows the cross-sectional view of FIG. 1B again without the references. Electrical connections electrically connecting the various elements of the depth pixel 5 to the readout circuit are schematically shown, but are not necessarily representative of a geometric arrangement in space.

The readout circuit comprises the first contact 161, a second contact 162, a third contact 163, a fourth contact 164, a sixth contact 166, and a seventh contact 167.

The pinning gates 114 are each electrically connected via their fourth contact 164 to a node or a rail for supplying an electric potential VLO2. The reset gate 113 is electrically connected via the third contact 163 to a node or a rail providing an electric potential TGRST. The reverse transfer gate 112 is electrically connected via the second contact 162 to a node or a rail for supplying an electric potential TGZ. The pinning zone 121 is electrically connected to a node or a rail for supplying an electric potential VLO1, via the seventh contact 167.

The readout circuit further comprises a transistor 53 configured as a source follower and a selection transistor 54. The transistors 53 and 54 are NMOS transistors here. The drain of the transistor 53 is electrically connected to a node or a rail for supplying an electric potential VSF. The source of the transistor 53 is electrically connected to the drain of the selection transistor 54. The source of the selection transistor 54 is electrically connected to an output line having an electric potential V_{X}. The output line is connected to a column footer of the array of pixels. The gate of the selection transistor 54 is electrically connected to a node or a rail for supplying an electric potential RD. The collection zone 125 is electrically connected to a sense node SN via the sixth contact 166. The sense node SN is electrically connected to the gate of the transistor 53. It is further electrically connected to a node or a rail for supplying an electric potential VRTRST via the channel of a reset transistor 57 of the readout circuit. The second switch 57 is controlled by an electric potential RST. This is an NMOS transistor here.

In relation to FIG. 2B, a possible operation of this readout circuit will be illustrated. FIG. 2B shows a timing diagram on which electric potentials varying over time have been reported. Some of these are marked with solid discs on the electrical diagram of FIG. 2A. Different bias states of the depth pixel 5 over the course of a cycle of the timing diagram are represented by elementary geometric shapes placed on a timeline.

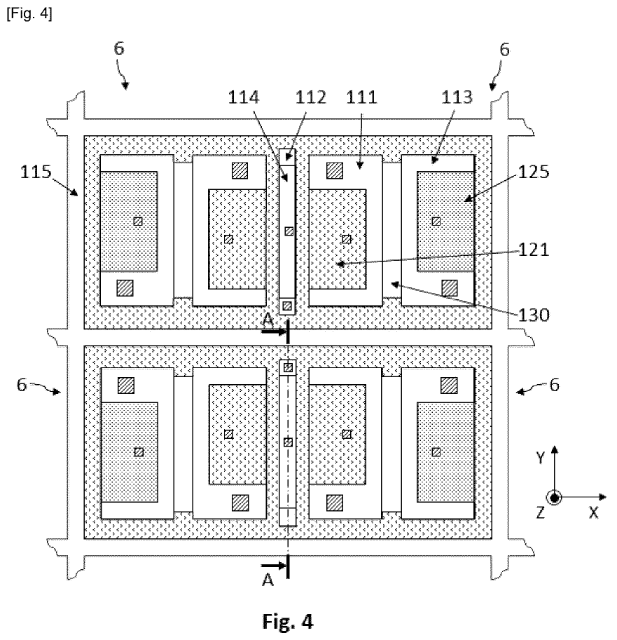

FIGS. 4A to 4D are diagrams illustrating the change in the electric potential throughout various regions of the depth pixel 5, corresponding to the bias states identified in FIG. 2B. The elementary geometric shape allowing to identify the corresponding bias state of the time diagram is drawn at the top left of each of FIGS. 4A to 4D. In these drawings, the axis of the ordinates gives the value of the electric potential in arbitrary units, at a position of the depth pixel 5 marked on the axis of the abscissae. The various regions of the depth pixel 5 are identified by dotted vertical lines and a reference placed opposite them on the axis of the abscissae. We successively go from the collection zone 125, to the collection channel 133, to the photosensitive region 120, to the barrier 131, to the memory region 135 and finally to the pinning zone 121.

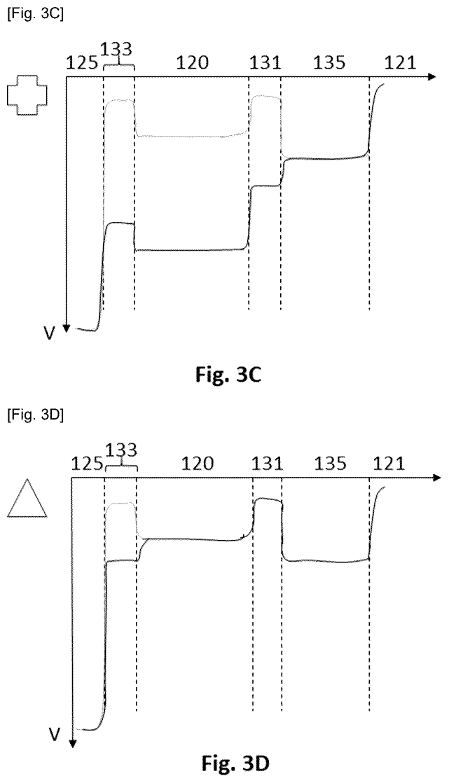

In each of FIGS. 3A to 3D, the change in the electric potential inside the depth pixel 5 when the electric potentials TGZ, TGMEM, TGRST, VLO2 are equal to −0.8V is schematically shown by a light gray line; VLO1 is equal to −0.5V, and the electric potential of the sense node SN is equal to 1.8V. A black line schematically shows the change in the potential for the corresponding bias state.

When a scene is illuminated by a light source emitting a light signal having a periodic amplitude having the period P_{S}, the timing diagram leads to an integration of a part of the light signal reflected by the scene, over periodic time intervals having a period equal to the period P_{S} and a duration equal to P_{S}/4.

The timing diagram is adapted to a sensor of an image comprising several depth pixels 5 arranged in an array. It successively comprises a reset phase T0, a sampling phase T1 and a phase of reading the array TM. The phase of reading the array TM consists of an optional first waiting phase T2, a first reading phase T3, a charge evacuation phase T4, a second reading phase T5 and an optional second waiting phase T6. The combination of the consecutive phases T0, T1 and TM constitutes a phase of acquiring a depth image, or acquiring a frame, for example if the sensor is capable of capturing several successive images. If applicable, the phase of reading the array TM of one frame can be immediately followed by the reset phase T0 of the next frame.

In order to determine depth information from the periodic light signal received by the sensor during a phase of acquiring an image, the depth pixel 5 can belong to a macro-pixel Z comprising several identical depth pixels 5. If applicable, the sampling phases T1 of distinct depth pixels 5 of the macro-pixel Z are offset by a fraction of a period P_{S}, modulo the period P_{S}. A macro-pixel Z can for example consist of 4 depth pixels 5 having their sampling phases T1 offset by a quarter of the period P_{S} between two phases, modulo the period P_{S}.

Alternatively, depth information can be determined from the periodic light signal received by the sensor during phases of acquiring successive frames. By way of example, the sampling phases T1 of successive frames can be offset by a quarter of the period P_{S} modulo the period P_{S}, or the light signal is offset by a quarter of the period P_{S} modulo the period P_{S} from one frame to the next. The depth information is then determined from the samples collected by the depth pixel 5 during the phases of acquiring the successive frames. Other arrangements are also possible, allowing to acquire a depth information from samples collected over several frames with a macro-pixel Z of at least one depth pixel 5.

During the phase of acquiring an image or a frame, the electric potentials VLO1, VLO2, VSF and VRTRST are fixed. By way of example, VLO1 is equal to −0.5V or 0V. VLO2 is for example equal to −0.8V. VSF is for example equal to 1.8V. VRTRST is for example equal to 1.8V or 2.5V.

VL02 is strictly less than VL01 so that holes coming from the pinning zone 121 are attracted along the pinning gate 114 by an electric field between the pinning zone 121 and the pinning gate 114. Thus, these holes form with the memory region 135 a lateral junction passivating the memory region 135.

The reset transistor 57 is kept on during the reset and sampling phases T0, T1, as well as during the first and second waiting phases T2, T6.

During the reset phase T0, the photosensitive region 120 and the memory region 135 are emptied of possible electric charges that they could contain. For this, the electric potentials TGRST, TGMEM, TGZ are initially all three equal to a high value V_{H}. The depth pixel 5 is in a bias state corresponding to FIG. 3A, for which the electric potential of the photosensitive region 120 is strictly greater than the electric potential of the barrier 131, which is in turn strictly greater than the electric potential of the memory region 135. Electrons contained in the memory region 135 thus flow, under the action of an electric field between the memory region 135 and the photosensitive region 120, from the memory region 135 to the photosensitive region 120.

TGMEM is then switched to a low value V_{L}, while TGRST and TGZ are maintained at the high value V_{H}. The value V_{L} is in this example equal to −0.8V. The value V_{H} is equal to 1.8V. The corresponding bias state is shown in FIG. 3C. For this state, the electric potential of the barrier 131 is strictly less than that of the photosensitive region 120, thus preventing the electrons from moving from the photosensitive region 120 to the memory region 135. In this state, the electric potential of the collection channel 133 is preferably strictly greater than the electric potential of the barrier 131, thus electric charges that cannot be contained in the photosensitive region 120 when it is at full capacity flow to the collection zone 125 rather than into the memory region 135.

Finally, TGZ is switched to the value V_{L}, while TGMEM and TGRST are maintained at V_{L} and V_{H}, respectively. This bias state corresponds to the situation in FIG. 3D for which no potential barrier is present between the photosensitive region 120 and the collection zone 125. For this state, the electric potential increases when passing from the photosensitive region 120 to the collection zone 125, while passing through the collection channel 133. Thus, an electric field internal to the depth pixel 5 drives electrons present in the photosensitive region 120, in particular those coming from the memory region 135, from the photosensitive region 120 to the collection zone 125. At the end of the reset phase T0, the memory region 135 and the photosensitive region 120 are substantially devoid of free electric charges; they are “reset”. They are at respective “pinch-off” electric potentials.

During the sampling phase T1, periodic pulse train is applied to the transfer gate 111. TGMEM is a periodic square wave having the period P_{S}, between V_{H} and V_{L}. Here, during each period of the square wave, TGMEM is equal to V_{H} for a duration equal to P_{S}/4. During this phase, TGRST switches between V_{H} and V_{L}, in phase opposition with respect to TGMEM. Thus, a switch is made from a bias state illustrated in FIG. 3B, for which photogenerated electric charges transit from the photosensitive region 120 to the memory region 135 during the pulses, to a bias state illustrated in FIG. 3D discussed above, for which electric charges transit from the photosensitive region 120 to the collection zone 125. At the end of the sampling phase T1, the memory region 135 contains an amount of photogenerated electric charges corresponding to a sample.

Throughout the sampling phase T1, the light signal is active (reference SL in the timing diagram). Preferably, the light signal SL is only active at the time of the sampling phase T1. Means, such as a clock or a synchronization signal, allow to synchronize the light signal with the readout circuit. These means can be external or integrated into the sensor, in whole or in part. Alternatively, the sensor can comprise means for blocking the light signal reflected by the scene before reaching the photosensitive region 120, outside of the sampling phase T1.

In FIG. 3B, the electric potential increases when passing from the photosensitive region 120 to the memory region 135, so that an internal electric field generates a movement of the electrons from the photosensitive region 120 to the memory region 135. The electrons are electrons photogenerated by the light signal, that is to say that they are electrons located in the conduction band of the photosensitive region 120 after the absorption of one or more photons of the light signal.

The first waiting phase T2 is a phase of waiting for selection of the row or column of the array to which the depth pixel 5 belongs. This phase is generally used to read other rows or columns. During this phase, TGZ and TGMEM are equal to V_{L}, while TGRST is equal to V_{H}. This situation is illustrated in FIG. 3D and discussed above. It allows to avoid possible additional electric charges generated in the photosensitive region 120 after the sampling phase T1 being transferred to the memory region 135 between the sampling phase T1 and the reading of the value of the sample collected in the memory region 135 during the sampling phase T1. The additional electric charges are evacuated to the collection zone 125. This function is sometimes called anti-blooming.

The first waiting phase T2 is followed by a first reading phase T3. The first reading phase T3 begins when the selection transistor 54 is switched to the on state (RD at a high value). The reset transistor 57 is then switched to an off state (RST at a low value). At the time when RST is switched, the light signal is already interrupted or blocked so that no electric charge is photogenerated by the light signal. The sense node SN is thus reset to an electric potential Vinit, substantially constant until the end of the first reading phase T3, corresponding to VRTRST plus an electric potential V_{kTC} corresponding to a thermal noise of the readout circuit. The value of the electric potential Vinit is read on the output line and stored at the column footer. The sense node SN has a capacity C_{SN}. The capacity C_{SN} is not necessarily an independent component of the readout circuit. It can be induced by various factors related to the design and the materials, for example such as interconnection lines, one or more transistor gates, etc.

A phase T4 of evacuating charges follows the first reading phase T3. The charge evacuation phase T4 is identical or similar here to the reset phase T0. It starts when TGZ and TGMEM switch to the high value V_{H}, TGRST being maintained at V_{H}. Preferably TGZ switches to V_{H} before TGMEM. The depth pixel 5 is then in the bias state of FIG. 3A. TGMEM is then switched to a low value V_{L}, while TGRST and TGZ are maintained at the high value V_{H}. The corresponding bias state is shown in FIG. 3C. At the end of the charge evacuation phase T4, TGZ is switched to the value V_{L}, while TGMEM and TGRST are maintained at V_{L} and V_{H}, respectively. This bias state corresponds to the situation in FIG. 3D.

Alternatively, TGMEM can be kept at the low value for the duration of the charge evacuation phase T4. TGZ switches from the high value V_{H} (situation in FIG. 3C) to the low value V_{L} (situation in FIG. 3D) during the charge evacuation phase T4.

At the end of the charge evacuation phase T4, the memory region 135 is emptied of the photogenerated electric charges that had been transferred from the photosensitive region 120 during the sampling phase T1. It returns to its pinch-off potential. The photogenerated charges reach the collection zone 125 and charge the capacity C_{SN} of the sense node SN to an electric potential Vsig.

The charge evacuation phase T4 is followed by a second reading phase T5. The second reading phase T5 begins after TGZ has been switched to the low value V_{L}, TGMEM and TGRST being respectively maintained at V_{L} and V_{H}, with it being understood that TGRST could also be equal to V_{L} during the second reading phase T5. The value of the electric potential Vsig is read on the output line and stored at the column footer. Vsig is representative of the number of electric charges photogenerated and collected in the memory region 135 during the sampling phase T1. The second reading phase T5 ends when the selection transistor 54 is switched to an off state (RD at a low value).

In this example, the sensor comprises means for carrying out a correlated double sampling. The means comprise in particular the first reading phase T3, the storage of Vinit read at the column footer and an analog cell producing a signal proportional to the difference between Vinit and Vsig. For example, the analog cell subtracts Vsig from Vinit. Since the readings of Vinit and Vsig are consecutive, without modification of the state of the reset transistor 57 between the first and second reading phases T3, T5, the reading of Vsig does not suffer from any thermal noise additional to that already present during the reading of Vinit. Thus, subtracting Vsig from Vinit allows to suppress the kTC noise. The readings of Vsig and Vinit are said to be correlated.

The second reading phase T5 is followed by an optional second waiting phase T6 during which other rows of the pixel array are optionally selected. The electric potentials of the timing diagram are at values identical to those of the first waiting phase T2. After the second waiting phase T6, for example immediately after, the phases of reset T0, sampling T1 and reading the array TM can be repeated to acquire another frame.

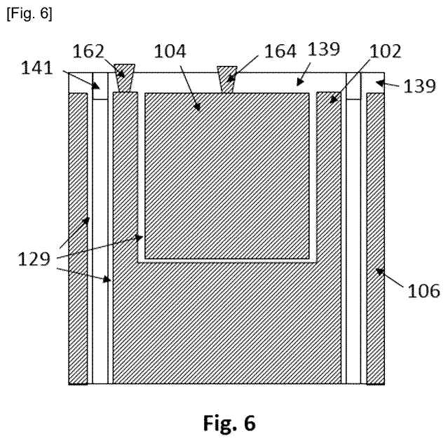

A sensor comprising an array of depth pixels 6 will now be described in relation with FIG. 4. All the depth pixels 6 are identical. Each depth pixel 6 is an alternative of the depth pixel 5 illustrated in FIGS. 1A and 1B. Only the differences between the alternative and the depth pixel 5 are explicitly described. FIG. 6 is a schematic view according to the section A-A of FIG. 4.

The reverse transfer gate 112 is flat. It extends according to a vertical plane parallel to the plane (Y, Z). The depth pixel 6 does not have an additional pinning gate 114. The pinning gate 114 extends in the same vertical plane as the reverse transfer gate 112. It occupies the notch made in the reverse transfer gate 112.

Each reverse transfer gate 112 and each pinning gate 114 are common to two contiguous depth pixels 6 of the array. The latter are for example symmetrical to each other with respect to the vertical plane according to which the reverse transfer gate 112 and the pinning gate 114 extend, as shown here.

Each depth pixel 6 comprises a peripheral isolation trench 115. The peripheral isolation trench 115 extends vertically in a peripheral region of the pixel opposite the additional flow path and the photosensitive region 120. It has, in this example, the shape of a U in a top view surrounding the additional flow path, the photosensitive region 120, the reset gate 113 and the transfer gate 111. It surrounds the pinning zone 121. It extends here from the upper face 100.1, preferably over a depth substantially equal to the thickness of the substrate 100.

In this example, the peripheral isolation trench 115 extends along 3 consecutive faces of the depth pixel 6 so as to completely cover them. Thus, the peripheral isolation trenches 115 of the array of two contiguous depth pixels 6 meet. They form a continuous mesh, such that each cell surrounds two contiguous depth pixels 6 of the array.

The peripheral isolation trench 115 comprises a vertical electrode 106 coated with a dielectric coating 129. The vertical electrodes 106 form a continuous, one-piece mesh. The dielectric coating 129 of the peripheral isolation trench 115 electrically insulates the vertical electrode 106 from the substrate 100. Here, the peripheral isolation trench 115 further comprises an insulating region 139 covering the vertical electrode 106 and flush with the upper face 100.1 of the substrate 100. The vertical electrode 106 is for example made of doped polycrystalline silicon. The dielectric coating 129 is for example made of silicon oxide. The insulating region 139 is for example made of silicon oxide. The mesh of vertical electrodes 106 is connected, for example at the periphery of the array, to a fixed electric potential allowing to passivate regions of the depth pixels 6 facing the peripheral isolation trenches 115.

The peripheral doped zones 141 of two depth pixels 6 in a cell meet at the plane of the reverse transfer gate 112, to form a one-piece zone.

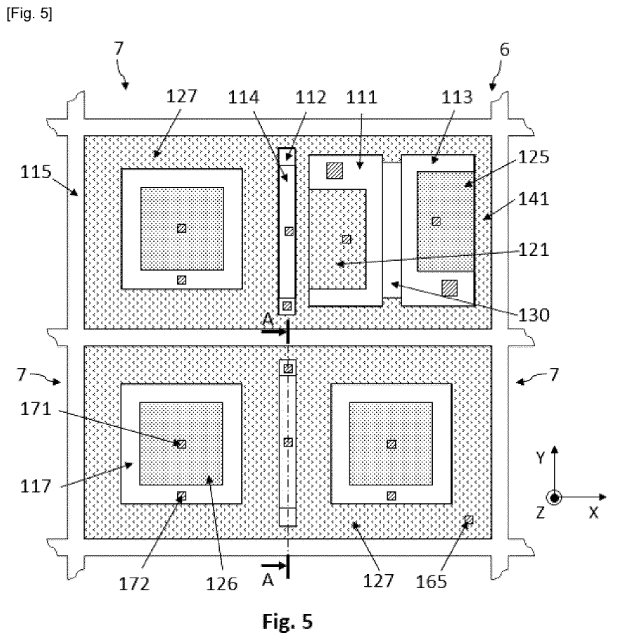

A sensor comprising an array of pixels mixing intensity pixels 7 and depth pixels 6 will now be described. Several intensity pixels 7 can be inserted into the array of pixels. FIG. 5 shows a set of 4 pixels of the array in a top view. FIG. 6 is a view according to the section A-A of FIG. 5. The set of 4 pixels is for example repeated periodically to form the array. Here, it comprises 3 intensity pixels 7 and one depth pixel 6. Only the differences with respect to the sensor of FIG. 4 are explicitly described. The depth and intensity pixels 6, 7 have superimposable horizontal footprints, that is to say that all their horizontal dimensions are equal.

The depth pixel 6 is identical to that described in relation to FIG. 4. Each intensity pixel 7 can be any type of pixel delivering a signal proportional to the intensity of a part of the electromagnetic radiation originating from the scene and incident on the lower face of the substrate 100, not comprising the light signal. The intensity pixel 7 can for example be a pixel similar to or identical to that described in the document US 2019/0237499 A1.

Each intensity pixel 7 comprises a transfer gate 117, a detection zone 126 and a well 127. It further comprises a peripheral isolation trench 115 identical to the depth pixel 6. The array of pixels of FIG. 5 is obtained by replacing depth pixels 6 of the array of FIG. 4 with intensity pixels 7. Thus, the peripheral isolation trenches 115 form a mesh identical to that of FIG. 4.

The detection zone 126 and the well 127 are doped with opposite types of conductivity. In this example, without this being essential, the well 127 is doped with the same type of conductivity as the pinning zone 121 and its peripheral doped zone 141. The well 127 and the pinning zone 121 can for example result from one or more shared implantation steps.

A first cell of the mesh formed by the peripheral isolation trenches 115 surrounds two intensity pixels 7. A second cell surrounds a depth pixel 6 with an intensity pixel 7. In the first cell, the wells 127 meet to form a one-piece doped zone. Similarly, in the second cell, the pinning zone 121 meets the well 127 to form another one-piece doped zone.

The transfer gate 117 extends vertically in the substrate 100 from the upper face 100.1. It has a substantially square or rectangular shape when viewed from above. It surrounds the detection zone 126 on all sides. The detection zone 126 extends from one edge to the other of the transfer gate 117. The well 127 extends from one edge to the other of a peripheral isolation trench 115. It surrounds the transfer gate 117.

Electric charges photogenerated in a photosensitive region of the intensity pixel 7 are collected in the detection zone 126 when the transfer gate 117 is activated. The transfer gate 117 is located vertically in line with this photosensitive region.

The depth pixel 6 does not share its reverse transfer gate 112 and its pinning gate 114 with a neighboring depth pixel 6. Advantageously, each intensity pixel 7 is separated from a neighboring pixel by a reverse transfer gate 112 and a pinning gate 114 identical to those of the depth pixel 6, and arranged in the same way. Thus, all the intensity pixels 7 have identical operating features. The reverse transfer and pinning gates 112, 114 of the first cell are advantageously biased by electric contacts, when the sensor is in operation.

For each intensity pixel 7, the detection zone 126 and the transfer gate 117 are connected to a control circuit by, respectively, a reading contact 171 and a gate contact 172. The control circuit can be a part of the readout circuit or an independent circuit. The wells 127 of the intensity pixels 7 of the first cell are connected to the control circuit by a fifth contact 165. In operation, the well 127 of the intensity pixel 7 of the second cell is biased here via the seventh contact 167 and the pinning zone 121.

By way of example, the sensor can be configured to capture a color image. The intensity pixels 7 of the set of 4 pixels can then each be sensitive in a range of wavelengths of the visible spectrum distinct from the other two intensity pixels 7 of the set. It is possible to associate them with a pixelized filter disposed opposite the lower face of the substrate 100, so that each pixel is exclusively sensitive to one of the three colors out of red, green or blue.

Specific embodiments have just been described. Various alternatives and modifications will be apparent to a person skilled in the art. The specific arrangement of the transfer and reverse transfer gates, between them and with respect to the flow path, is in particular an element essential to the bidirectional transfer between the photosensitive region and the memory region allowing to achieve the compactness goal of the invention. The latter can be used in similar depth pixels, connected to other types of readout circuits.

1. An image sensor comprising a readout circuit and a plurality of pixels formed in and/or on a semiconductor substrate of the sensor, such that at least one of the pixels is a depth pixel, each depth pixel comprising:
a photosensitive region of the substrate,
a controllable storage zone comprising:
a charge-flow path extending vertically in the substrate in vertical alignment with
the photosensitive region and comprising a memory region which is a potential well and a barrier which is a potential barrier interposed between the memory region and the photosensitive region,
a transfer gate extending vertically in the substrate vertically in line with the photosensitive region, opposite the barrier,
a reverse transfer gate extending vertically in the substrate opposite the barrier and opposite an upper part of the photosensitive region,
an additional path charge-flow path extending vertically in the substrate vertically in
line with the photosensitive region comprising a collection zone which is a potential well and a collection channel which is a potential barrier, interposed between the collection zone and the photosensitive region,
a reset gate extending vertically in the substrate vertically in line with the photosensitive region, and facing the collection channel,
wherein the readout circuit comprises a sense node electrically connected to the collection zone and is configured to successively:
apply a periodic pulse train to the transfer gate during a sampling phase so as to make electric charges flow from the photosensitive region to the memory region during the pulses,
reset the sense node,
activate the reverse transfer gate and the reset gate so as to make electric charges flow from the memory region to the collection zone during a charge evacuation phase,
read an electric potential Vsig of the sense node.

2. The image sensor according to claim 1, wherein the readout circuit is configured to read an electric potential Vinit of the sense node prior to the charge evacuation phase and after the reset of the sense node, wherein the image sensor is configured to perform correlated double sampling using Vinit and Vsig.

3. The image sensor according to claim 1, wherein the charge-flow path of the controllable storage zone comprises a pinning zone covering the memory region on a side of the memory region opposite to the barrier, wherein the controllable storage zone comprises a pinning gate extending vertically in the substrate facing the memory region, and wherein the readout circuit is configured to apply a difference in electric potential between the pinning zone and the pinning gate so as to passivate the memory region using electric charges coming from the pinning zone.

4. The image sensor according to claim 3, wherein the pinning gate is housed in a notch made in the reverse transfer gate.

5. The image sensor according to claim 1, wherein the readout circuit is further configured to activate the transfer gate during the charge evacuation phase after the activation of the reverse transfer gate.

6. The image sensor according to claim 1, wherein the readout circuit is configured to activate the reset gate in opposite phase to the transfer gate during the sampling phase.

7. The image sensor according to claim 1, wherein, for each depth pixel, the transfer gate extends facing the memory region.

8. The image sensor according to claim 1, wherein, for each depth pixel, the barrier, the memory region and the collection zone are doped with a first type of conductivity, and have dopant concentrations respectively equal to N1, N2, N3 such as N1 is strictly less than N2, and N2 is strictly less than N3.

9. The image sensor according to claim 8, wherein the charge-flow path of the controllable storage zone comprises a pinning zone covering the memory region on a side of the memory region opposite to the barrier, wherein the controllable storage zone comprises a pinning gate extending vertically in the substrate facing the memory region, and wherein the readout circuit is configured to apply a difference in electric potential between the pinning zone and the pinning gate so as to passivate the memory region using electric charges coming from the pinning zone and wherein, for each depth pixel, the pinning zone is doped with a second type of conductivity opposite to the first type of conductivity.

10. The image sensor according to claim 8, wherein the collection channel has a dopant concentration equal to N1.

11. The image sensor according to claim 8, wherein, for each depth pixel, the transfer gate has the shape of a U in a top view, surrounding the charge-flow path of the controllable storage zone.

12. The image sensor according to claim 1, wherein the plurality of pixels is arranged in an array, wherein each pixel comprises a peripheral isolation trench extending vertically in a peripheral region of the pixel facing a photosensitive region of the pixel and wherein the readout circuit is configured to apply a common fixed electric potential to all the peripheral isolation trenches.

13. The image sensor according to claim 12, wherein the charge-flow path of the controllable storage zone comprises a pinning zone covering the memory region on a side of the memory region opposite to the barrier, wherein the controllable storage zone comprises a pinning gate extending vertically in the substrate facing the memory region, and wherein the readout circuit is configured to apply a difference in electric potential between the pinning zone and the pinning gate so as to passivate the memory region using electric charges coming from the pinning zone and wherein each pinning gate and each reverse transfer gate are arranged in separation planes of two contiguous pixels of the array of pixels.

14. The image sensor according to claim 13, wherein the peripheral isolation trenches form a continuous mesh comprising cells such that each cell surrounds two pixels, and wherein the readout circuit is electrically connected to a peripheral zone of the mesh so as to apply the common fixed electric potential.

15. The image sensor according to claim 12, wherein all the pixels of the array have the same size, and wherein the array of pixels comprises intensity pixels configured to deliver a signal representative of an intensity of an incident light radiation.
